(19) United States
(12) Patent Application Publication
(10) Pub. No.: US 2022/0080549 A1
(43) Pub. Date: Mar. 17, 2022

(54) METHOD FOR POLISHING A SEMICONDUCTIOR WAFER

(71) Applicant: SILTRONIC AG, Munich (DE)

(72) Inventors: Alexander HEILMAIER, Haiming (DE); Vladimir DUTSCHKE, Lengefeld (DE); Leszek MISTUR, Burghausen (DE); Torsten OLBRICH, Dresden (DE); Dirk MEYER, Brand-Erbisdorf (DE); Vincent NG, Singapore (SG)

(73) Assignee: SILTRONIC AG, Munich (DE)

(21) Appl. No.: 16/968,689

(22) PCT Filed: Feb. 5, 2019
(86) PCT No.: PCT/EP2019/052729

§ 371 Date: Nov. 17, 2020

(30) Foreign Application Priority Data
Feb. 9, 2018 (DE) 102018202059.0

(51) Int. Cl. B24B 37/20; B24B 37/07; B24B 37/005

(52) U.S. Cl. CPC B24B 37/20; B24B 37/005; B24B 37/07

(57) ABSTRACT

Semiconductor wafers are polished simultaneously on both the front and the rear sides between an upper polishing plate and a lower polishing plate, each covered with a polishing pad, wherein a polishing gap (x₁+x₂) corresponding to a difference in the respective distances between facing surfaces of upper polishing pad and lower polishing pad which come into contact with the semiconductor wafer at the inner edge and at the outer edge of the polishing pads is changed incrementally or continuously during the polishing process.

### CROSS REFERENCE TO RELATED APPLICATIONS

This application is the U.S. National Phase of PCT Appln. No. PCT/EP2019/052729 filed Feb. 5, 2019, which claims priority to German Application No. 10 2018 202 059.0 filed Feb. 9, 2018, the disclosures of which are incorporated in their entirety by reference herein.

### BACKGROUND OF THE INVENTION

### 1. Field of the Invention

The invention relates to a method for polishing a semiconductor wafer.

### 2. Description of the Related Art

The wafers sawn from a single crystal of semiconductor material are usually planarized in various work steps:
a. mechanical processing (lapping, grinding)
b. chemical processing (alkaline or acidic etch)
c. chemomechanical processing: single-side polishing, double-side polishing (DSP) and single-side haze-free or mirror polishing using a soft polishing pad (CMP).

The mechanical processing of the semiconductor wafers serves primarily for the global leveling of the semiconductor wafer, and also for the removal of the crystalline-damaged surface layer and processing traces (sawing grooves, incision mark) caused by the preceding separation process.

In the case of etching, contaminants and/or native oxides are removed chemically from the surface of the semiconductor wafers.

Final smoothing of the surfaces of the semiconductor wafer is finally effected by means of chemical mechanical polishing.

The present invention relates to double-side polishing (DSP), a method from the group of chemomechanical processing steps.

In accordance with an embodiment described in the patent specification EP 0208315 B1, semiconductor wafers in carrier plates composed of metal or plastic, which have suitably dimensioned cutouts, are moved between two rotating polishing plates covered with a polishing pad, a working gap being formed between the polishing plates, in the presence of a polishing agent on a path predetermined by the machines and process parameters, and are thereby polished.

DE 10 2013 201 663 A1 discloses a method for double-side polishing in which the required wafer geometry is achieved by a targeted working gap being set by the processing of the polishing pads, the distance between the upper and lower polishing pads being larger in the inner region than in the outer region.

In addition, DE 10 2006 037 490 B4 discloses an apparatus which can be used to set the polishing gap independently of the mechanically prepared gap. This is made possible by virtue of the fact that the convexity or concavity of the upper polishing plate is able to be set in a continuously variable manner.

In accordance with DE 11 2013 006 059 T5, the working gap is adjusted by bellows on the basis of the flatness of the wafers (measurement of already processed wafers).

According to DE 10 2010 024 040 A1, the shape of one of the two polishing plates is mechanically or thermally deformed in order to achieve an optimum working gap.

The solutions proposed in the prior art aim to optimize the geometry of the semiconductor wafers. To that end, a suitable working gap is set for the polishing process.

One problem consists in the fact that the choice of a geometry-optimizing working gap is generally associated with a low removal rate and hence with a low throughput.

It is an object of the invention to improve the prior art and in particular to achieve an optimized geometry during the polishing of a semiconductor wafer and at the same time a high removal rate.

### SUMMARY OF THE INVENTION

The invention relates to a method for polishing a semiconductor wafer which is polished simultaneously on both sides on the front side and on the rear side between an upper polishing plate (11) and a lower polishing plate (12), which are respectively covered with a polishing pad (21, 22), wherein a polishing gap (x₁+x₂) corresponding to a difference in the respective distances between those surfaces of upper polishing pad (21) and lower polishing pad (22) which come into contact with the semiconductor wafer at the inner edge (B) and at the outer edge (A) of the polishing pads (21, 22) is changed in its size in stages or continuously variably during the polishing method.

### BRIEF DESCRIPTION OF THE DRAWINGS

FIG. 1 shows two polishing plates covered with polishing pads, and also the polishing gap.

FIGS. 2-7 in each case show the change in the polishing gap over time until the end of the polishing process in accordance with a preferred embodiment of the method.

### DETAILED DESCRIPTION OF THE PREFERRED EMBODIMENTS

Embodiments of this method can be gathered from the following description, the figures and the dependent claims.

### List of Reference Signs Used

1 polishing plate
11 upper polishing plate
12 lower polishing plate
2 polishing pad
21 upper polishing pad
22 lower polishing pad
A outer edge/region of polishing plate/polishing pad
B inner edge/region of polishing plate/polishing pad
x₁ upper polishing gap
x₂ lower polishing gap

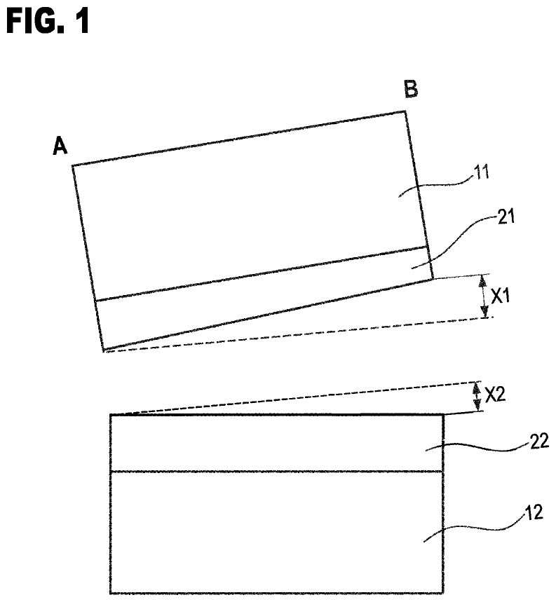

Preferably, a distance between the upper polishing pad 21 and the lower polishing pad 22 is larger in the inner region B than in the outer region A. This embodiment is illustrated in FIG. 1. The difference between the two distances at the inner edge A and at the outer edge B or the sum of upper polishing gap x₁ and lower polishing gap x₂ yields the polishing gap x₁+x₂. The working gap has the shape of a wedge in this case.

Likewise, a distance between the upper polishing pad 21 and the lower polishing pad 22 in the inner region B can be almost equal in magnitude to that in the outer region A. In this case, the polishing gap x₁+x₂ is very small, close to zero. In one embodiment of the method, the polishing pass is begun with a smaller polishing gap x₁+x₂ (almost parallel working gap, i.e. polishing pad surfaces are almost parallel) in order, at the beginning of the process, to place the upper polishing plate 11 onto the lower polishing plate 22 as parallel as possible and thus to avoid wafer breaking and to start the process gently. During a short ramp, the polishing gap x₁+x₂ is then increased to a larger value.

What is essential to the invention is that the polishing gap x₁+x₂, defined as the difference in the distances between the upper polishing pad 21 and the lower polishing pad 22 in the inner region B and in the outer region A, is varied during the polishing. This can be done in one or more stages or else continuously, that is to say continuously variably.

The method according to the invention is based on the observation that a relatively small polishing gap x₁+x₂ is required for a good wafer geometry (e.g. GBIR, ESFQR), but this results in a relatively small removal rate, whereas a relatively large polishing gap x₁+x₂ has a relatively large removal rate, but causes a poorer geometry.

In one embodiment, the invention provides for starting the process with a large polishing gap x₁+x₂ or transitioning to a large polishing gap x₁+x₂ after a gentle start with a small polishing gap x₁+x₂, wherein a small polishing gap x₁+x₂ is set toward the end of the process. The final polishing step with a small removal rate serves for optimizing the geometry, while the preceding polishing step(s) is(are) carried out with a high removal rate. The polishing step with a small polishing gap is essential in order to ensure the required geometry of the semiconductor wafer.

The polishing gap x₁+x₂ can be set by deformation of the polishing plates 1. Before the process starts, if appropriate, the polishing pads 2 are processed (dressing), wherein the shape of the polishing pads 2 after dressing likewise makes a contribution to the polishing gap x₁+x₂. Consequently, the geometry of the working gap and also the polishing gap x₁+x₂ (as the difference between the distances at the inner and outer areas) result from a combination of polishing plate and polishing pad geometry.

In one embodiment of the invention, before the double-side polishing of a semiconductor wafer, so-called pad dressing is carried out between the polishing pads 2 secured in this way on the polishing plates 1. In this case, before the polishing process, the polishing pads 2 adhesively bonded on the polishing plates 1 are adapted to the respective individual polishing plate shape of the polishing machine. Corresponding methods are known in principle from the prior art and described for example in the documents EP 2 345 505 A2 or U.S. Pat. No. 6,682,405 B2. Pad dressing is advantageous since a polishing plate 1 may usually have differences in the local flatness of up to ±50 μm. It serves to set a desired polishing pad geometry and thus a desired initial working gap geometry and also the desired properties of the pad surface of the polishing pad 2 by means of mechanical processing of the polishing pad 2 situated on the polishing plate 1 by means of suitable tools, generally comprising diamond abrasive bodies.

The invention relates to the simultaneous polishing of the front side and the rear side (DSP) of at least one semiconductor wafer, wherein semiconductor materials are compound semiconductors such as preferably for example gallium arsenide or elemental semiconductors such as principally silicon, but also germanium, or else layer structures thereof.

DSP polishing pads 2 are usually ring-shaped, wherein a circular cutout for the polishing machine mechanisms, such as a rotary shaft for the rotary drive, is situated in the center of the polishing pad surface.

During DSP, an undesired rounding of the wafer edge (Edge-Roll-Off, ERO) generally occurs. This rounding, which leads to a poor edge geometry, is dependent, inter alia, on how far the semiconductor wafer sinks into the upper polishing pad 21, the lower polishing pad 22 or into both polishing pads 2 during polishing. As a result of the semiconductor wafer sinking into the polishing pad 2, material-removing forces acting on the edge are higher than those acting on the rest of the surface.

In order that sinking of the semiconductor wafer into the polishing pad 2 during polishing is minimized or completely avoided, polishing pads 2 having a high pad hardness and a low pad compressibility are preferably used in the method according to the invention.

Preferably, a hard polishing pad 2 has a hardness according to Shore A of preferably 80-100°. One suitable, commercially available polishing pad 2 is for example the EXTERION™ SM-11D from Nitta Haas Inc. having a hardness of 85° according to JIS-A. Pads of the type MH-S24A from Nitta Haas Inc. are specified for example with a hardness of up to 86 JIS-A (JIS K 6253A), wherein a hardness according to JIS-A corresponds to a hardness according to Shore A.

Unless indicated otherwise, all parameters were determined at a pressure of the surrounding atmosphere, that is to say at approximately 1000 hPa, and at a relative air humidity of 50%.

The hardness according to Shore A is determined in accordance with DIN EN ISO 868. A type A durometer (hardness testing apparatus Zwick 3130) is used. The tip of the hardened steel rod presses into the material. The indentation depth is measured on a scale of 0-100. The steel pin has the geometry of a truncated cone. Five measurements are carried out in each case and the median value thereof is indicated. The measurement time is 15 s; the material to be tested was stored for 1 h under standard conditions (23° C., 50% air humidity). The press-on weight of the durometer is 12.5 N±0.5.

Preferably, a polishing pad 2 having a low compressibility has a compressibility of 0.2% to less than 3%. More preferably, the compressibility of the polishing pad 2 is less than 2.5%. Most preferably, the compressibility of the polishing pad 2 is less than 2.0%.

The compressibility of a material describes what pressure change on all sides is necessary to bring about a specific change in volume. The compressibility is calculated analogously to JIS L-1096 (Testing Methods for Woven Fabrics).

After a defined pressure, for example 300 g/cm², has been applied to the pad surface, the pad thickness T1 is measured after one minute. Afterward, the pressure is increased to 6 times the first pressure, here 1800 g/cm², and the pad thickness T2 is measured after one minute. From the values T1 and T2, the compressibility of the polishing pad is calculated using the formula compressibility [%]32 (T1−T2)/T1×100.

Both foamed polishing pads 2 (foamed pads) and polishing pads 2 having a fibrous structure (non-woven pads) are suitable as polishing pads 2 having a high pad hardness and a low pad compressibility.

Preferably, the polishing pad 2 has a porous matrix. Preferably, the polishing pad 2 consists of a thermoplastic or heat-curable polymer and has a porous matrix (foamed pad).

As material, a multiplicity of materials preferably come into consideration, e.g. polyurethanes, polycarbonate, polyimide, polyacrylate, polyester, etc.

Preferably, the polishing pad 2 consists of solid microporous polyurethane.

Preference is also given to the use of polishing pads 2 composed of foamed plates or felt or fibrous substrates impregnated with polymers (non-woven pad).

In the method according to the invention, the thickness of the polishing pad 2 is preferably in the range of 0.5 to 1.3 mm, more preferably in the range of 0.5 to 0.9 mm.

For the purpose of polishing, the semiconductor wafers are placed into a suitably dimensioned cutout of a carrier plate. Preferably, a liquid is fed into the working gap formed between the working layers of the polishing pads 2 during polishing. This liquid is preferably a polishing agent slurry. The use of colloidally disperse silica, if appropriate with additives such as e.g. sodium carbonate (Na₂CO₃), potassium carbonate (K₂CO₃), sodium hydroxide (NaOH), potassium hydroxide (KOH), ammonium hydroxide (NH₄OH), tetramethylammonium hydroxide (TMAH), as polishing agent slurry is particularly preferred.

The polishing gap x₁+x₂ between the two corresponding polishing plates 1 (respectively covered with polishing pads 2) ranges between 0 μm and 220 μm.

In the method according to the invention, the different distances (heights) in the polishing gap x₁+x₂ are achieved by means of a deformation of at least one of the two polishing plates 1. Consequently, a double-side polishing machine in which at least one of the two polishing plates 11, 12 can be deformed in a targeted manner during polishing is preferably suitable for the method according to the invention.

In one embodiment, the method comprises a polishing step with a large polishing gap x₁+x₂ having a size of 130 μm to 220 μm and a polishing step with a small polishing gap x₁+x₂ having a size of 50 μm-110 μm.

The working gap can be of linear and nonlinear (convex or concave) configuration.

The polishing gap x₁+x₂ results from the difference in the distance between the surfaces of the upper polishing pad 21 and the lower polishing pad 22 of the two corresponding polishing plates 1 at the inner polishing plate edge B of the working gap and the distance between the surfaces of the upper polishing pad 21 and the lower polishing pad 22 of the two corresponding polishing plates 1 at the outer polishing plate edge A of the working gap, wherein the center of the polishing plate 1 has a circular cutout (for the rotary shaft of the rotary drive) that forms the inner polishing plate edge B.

During the simultaneous double-side polishing of the semiconductor wafer using hard polishing pads having low compressibility, a surface removal of less than or equal to 15 μm per side is preferably effected, wherein the range of preferably 4 μm to 10 μm is particularly preferred in this regard.

The method has an increased economic viability by comparison with known DSP processes since overall significantly higher removal rates result, wherein the required geometry of the semiconductor wafer is achieved.

In one embodiment of the method, the ratio of small polishing gap x₁+x₂ to large polishing gap x₁+x₂ is preferably 1:4 to 3:4.

To put this another way: if the large polishing gap x₁+x₂ is 100%, the small polishing gap x₁+x₂ is preferably 25% to 75%.

The large polishing gap x₁+x₂ is preferably 150 to 220 μm, more preferably 150 to 190 μm, while the small polishing gap x₁+x₂ is preferably 0 to 130 μm, 70-120 μm, and more preferably 50 to 110 μm.

In one embodiment, a two-stage method is involved by virtue of the fact that the first stage has a larger polishing gap x₁+x₂ at the beginning of the method and the second stage at the end of the method has a smaller polishing gap x₁+x₂, wherein the first step preferably lasts for 80-90% of the polishing time and the second step preferably lasts for 10-20% of the polishing time, wherein the polishing gap x₁+x₂ decreases in size from the first stage to the last stage by preferably 60% to 20%.

The polishing step with the large polishing gap x₁+x₂ is intended to last for as long as possible in order to achieve the highest possible removal rate. However, the step with the small polishing gap x₁+x₂ must be long enough to ensure a good geometry.

In one embodiment, a multi-stage method is involved by virtue of the fact that the first stage has a large polishing gap x₁+x₂ at the beginning of the method and has ever smaller polishing gaps x₁+x₂ in the further stages at the end of the method, wherein, in a multi-stage method, the reduction of the polishing gap x₁+x₂, which begins at 100%, with respect to the preceding larger polishing gap x₁+x₂ is in the range of preferably 10% to 40% of the last preceding polishing gap x₁+x₂.

By way of example, the initial polishing gap x₁+x₂ is 100% and, in the next polishing stage, the polishing gap x₁+x₂ has 75% of the first polishing gap x₁+x₂ and has thus decreased by 25% or, in the next polishing stage, the polishing gap x₁+x₂ has 60% of the magnitude of the first polishing gap x₁+x₂ and has thus decreased by a total of 40%.

By way of example, the polishing gap x₁+x₂ could initially be 200 μm. In a first stage, the polishing gap x₁+x₂ is reduced by 10% to 180. In a further stage, the polishing gap is reduced by 33% to 120. In the final stage, the polishing gap x₁+x₂ is reduced by 16.7% to 100.

In one embodiment, in a four-stage polishing method, the first three stages with a large polishing gap x₁+x₂ occupy a total of 80-90% of the polishing time and the last stage with the smallest polishing gap x₁+x₂ preferably occupies 10-20% of the polishing time. In principle, the first three stages can each take up different polishing times; in this regard, e.g. the first stage can also amount to 40%, the second stage 30% and the third stage 20% and the last stage 10% of the total polishing time.

If the size of the polishing gap x₁+x₂ is 100% in the first stage, the size of the polishing gap in the following polishing stage, preferably in the second stage, is 75% of the initial magnitude of 100%, the size of the polishing gap x₁+x₂ in the third stage is preferably 60% of the initial magnitude of 100%, and the size of the polishing gap x₁+x₂ in the last stage is preferably 50% of the initial magnitude of 100%, of the largest polishing gap, wherein the size of the polishing gap x₁+x₂ in the individual stages can preferably assume different values with respect to one another.

In one embodiment, in a first step, the polishing gap x₁+x₂ is continuously decreased. At the beginning of a second step, the continuous decrease in the polishing gap x₁+x₂ is ended and with the polishing gap x₁+x₂ that the machine has at this point in time the polishing method is continued for a specific time duration and finally ended. If the polishing gap x₁+x₂ starts at 100% and ends at 50% of the initial polishing gap x₁+x₂, the polishing gap x₁+x₂ is continuously reduced e.g. from 200 μm to 100 μm for a time period of 80-90% of the total polishing time. For a time period of 10-20% of the total polishing time, in the last step, polishing is then carried out with 50% of the initial polishing gap x₁+x₂ (100 μm).

The rate of reduction of the magnitude of the polishing gap x₁+x₂ can preferably amount linearly or else nonlinearly to preferably 80-90% of the total polishing time, wherein the last polishing step can preferably also form an individual stage which preferably amounts to 10-20% of the total polishing time.

In a further embodiment, the method starts with a higher polishing gap x₁+x₂ in order to pass via a plurality of stages in each case to a stage with a smaller magnitude of the polishing gap x₁+x₂, wherein in each case in each polishing stage the polishing gap x₁+x₂ is increased again within the respective stage, wherein the polishing gap x₁+x₂ in the respective next stage is first reduced in magnitude in order then to increase again in magnitude.

In another embodiment, the process starts with a parallel or almost parallel polishing gap x₁+x₂ between the two corresponding polishing plates, in the case of which the difference in the distance between the two polishing plates 1 in the inner region B and the distance between the two polishing plates 1 in the outer region A is equal to or almost 0 μm, in order then to continue the polishing method with a large polishing gap x₁+x₂, e.g. 200 μm, wherein the polishing gap x₁+x₂ is subsequently reduced in stages or continuously as in one of the embodiments described above.

The last polishing step, that is to say the one with the smallest polishing gap x₁+x₂, should make up at least 10% of the total polishing time, wherein the small polishing gap x₁+x₂ is preferably 120 μm to 70 μm, more preferably 110 μm to 80 μm.

The polishing steps with a relatively small polishing gap x₁+x₂ can be carried out at a relatively low polishing pressure of approximately 110-150 g/cm².

The removal steps with a relatively large polishing gap x₁+x₂ should be carried out at a polishing pressure of e.g. 150-200 g/cm².

In one embodiment, the polishing pressure is regulated analogously to the polishing gap x₁+x₂.

In one embodiment of the method, a polishing step is variable in terms of time duration. Preferably, this polishing step is the penultimate polishing step.

In one embodiment, an in-situ thickness measurement of the semiconductor wafer is provided. Suitable sensors for in-situ thickness measurement in polishing machines are known.

In one embodiment, an in-situ thickness measurement is carried out, wherein the result of the measurement is used to temporally vary a polishing step, in particular the or one of the removal step(s) with a large polishing gap x₁+x₂. The temporally variable polishing step is adapted, that is to say lengthened or shortened with regard to the time duration, in such a way that the semiconductor wafer has the desired target thickness at the end of the process.

The last, geometry-optimizing polishing step can also be variable in terms of time duration, wherein this time duration is dependent on the result of the in-situ thickness measurement of the semiconductor wafer during the process. The last polishing step can be lengthened or shortened by the time duration required to reach the desired thickness of the semiconductor wafer.

As a further processing process, chemical mechanical polishing of only the front side of the semiconductor wafer (so-called CMP) comes into consideration, as is known for example from DE 10 2008 045 534 B4. In this case, a semiconductor wafer is pressed onto a polishing pad (which can be situated on a polishing plate) by means of a carrier and is then moved usually in rotary fashion under pressure. The front side of the semiconductor wafer is then polished by the use of a suitable polishing agent or polishing agent slurry. The CMP of the front side can be carried out in one or more steps. The CMP involves one or more smoothing steps (without significant removal of semiconductor material).

If appropriate, the CMP is followed by a coating process in which a layer is deposited epitaxially onto the CMP-polished front side of the semiconductor wafer. This step comprises depositing the epitaxial layer on the front side of the semiconductor wafer by means of vapor deposition (chemical vapor deposition, CVD). A CVD carried out in a single-wafer reactor under standard pressure (atmospheric pressure) is particularly suitable. U.S. Pat. No. 5,355,831 A publishes typical method parameters of such a method, which can be regarded as by way of example.

The features specified with regard to the embodiments of the method according to the invention as presented above can be realized either separately or in combination as embodiments of the invention. Furthermore, they can describe advantageous embodiments which are independently protectable.

The term polishing gap and some embodiments of the method according to the invention are explained below with reference to figures.

### FIGURES

FIG. 1 shows the size of the polishing gap. An upper polishing plate 11 and a lower polishing plate 12 are illustrated, wherein the polishing pad 21 of the upper polishing plate 11 is thicker at the outer edge A than at the inner edge B. By contrast, the polishing pad 22 of the lower polishing plate 12 is of the same thickness at the outer edge A and at the inner edge B. In conjunction with the deformed polishing plates 11 and 12, this results in a polishing gap having the size x₁+x₂.

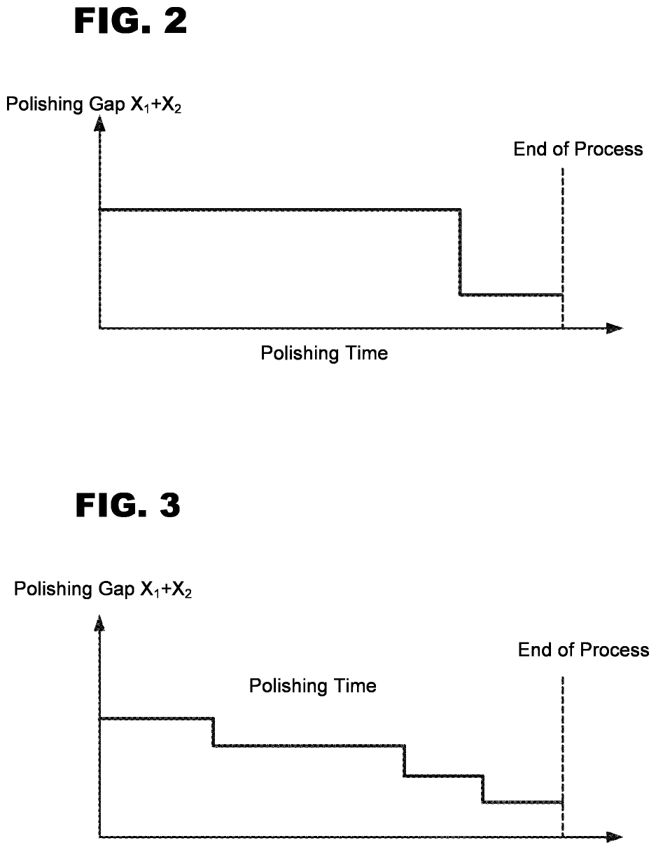

FIG. 2 shows the change in the polishing gap x₁+x₂ over time until the end of the polishing process in accordance with one embodiment of the method. A two-stage method is involved, wherein the polishing gap x₁+x₂ is firstly constant, is reduced at a specific point in time and is then kept constant once again until the end of the process.

FIG. 3 shows the change in the polishing gap x₁+x₂ over time until the end of the polishing process in accordance with a further embodiment of the method. A multi-stage method is involved, wherein the polishing gap is reduced at three points in time, wherein the polishing gap is kept constant in each case before and after these points in time. The process comprises four phases each having constant polishing gaps.

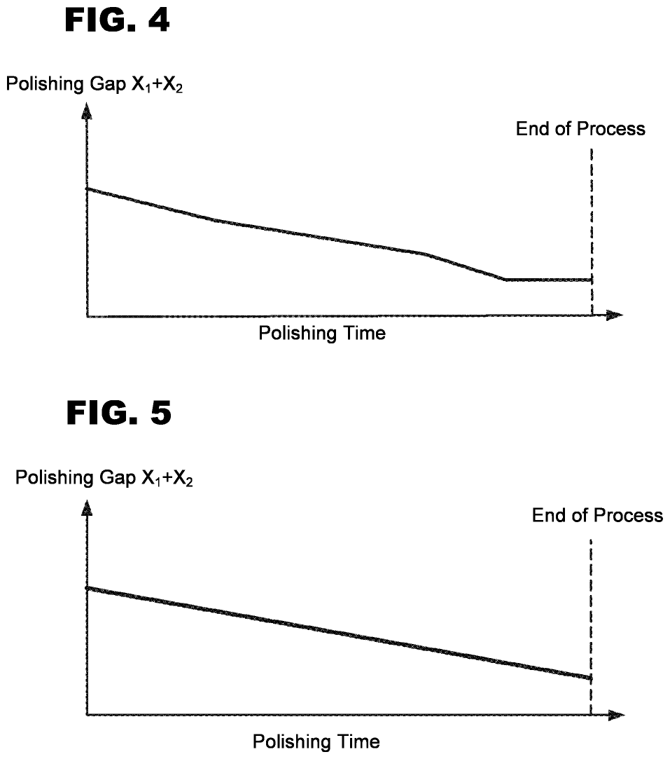

FIG. 4 shows the change in the polishing gap over time until the end of the polishing process in accordance with a further embodiment of the method. This is a continuous method without continuously variable transitions. The method comprises various polishing steps within which the polishing gap is continuously reduced. Toward the end of the process, a polishing step is provided in which the polishing gap is kept constant.

FIG. 5 shows the change in the polishing gap over time until the end of the polishing process in accordance with a further embodiment of the method. This is once again a continuous method without continuously variable transitions. The method comprises only one polishing step, in which the polishing gap is continuously reduced.

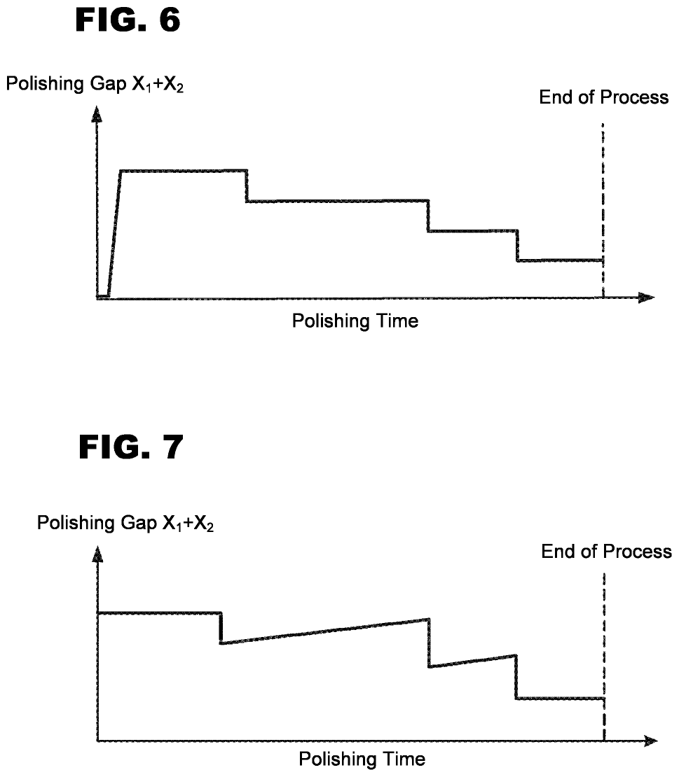

FIG. 6 shows the change in the polishing gap over time until the end of the polishing process in accordance with a further embodiment of the method.

This is a multi-stage method which starts initially with a polishing gap with 0 μm.

FIG. 7 shows the change in the polishing gap over time until the end of the polishing process in accordance with a further embodiment of the method. The method starts in each case with a higher polishing gap in order to pass via a plurality of stages in each case to a stage with a smaller magnitude of the polishing gap, wherein in each case in each polishing stage the polishing gap is increased again within the respective stage, wherein the polishing gap in the next stage is first reduced in magnitude in order then to increase again in magnitude. In the next stage, the polishing gap is reduced again in magnitude in order then to increase in magnitude within this stage.

The above description of exemplary embodiments should be understood to be by way of example. The disclosure thus given firstly enables the person skilled in the art to understand the present invention and the advantages associated therewith, and secondly also encompasses, within the understanding of the person skilled in the art, obvious alterations and modifications of the structures and methods described. Therefore, all such alterations and modifications and also equivalents are intended to be covered by the scope of protection of the claims.

1.-18. (canceled)

19. A method for polishing a semiconductor wafer which is polished simultaneously on both the front side and the rear side between an upper polishing plate and a lower polishing plate which are each covered with a polishing pad, wherein a polishing gap (x₁+x₂) corresponding to a difference in the respective distances between facing surfaces of the upper polishing pad and lower polishing pad which come into contact with the semiconductor wafer at the inner edge and at the outer edge of the upper and lower polishing pads is changed during the polishing method.

20. The method of claim 19, wherein the polishing gap (x₁+x₂) is changed in increments.

21. The method of claim 19, wherein the polishing gap (x₁+x₂) is changed continuously.

23. The method of claim 19, wherein the first stage at the beginning of the method has a larger polishing gap (x₁+x₂) and the second stage at the end of the method has a smaller polishing gap (x₁+x₂).

24. The method of claim 19, wherein the polishing gap (x₁+x₂) is reduced in its size in stages.

25. The method of claim 19, comprising at least two polishing steps, wherein the polishing gap (x₁+x₂) in the second polishing step is 25% to 75% of the polishing gap (x₁+x₂) in the first polishing step.

26. The method of claim 19, wherein in a first polishing step the polishing gap (x₁+x₂) is reduced in size continuously, then the reduction of the polishing gap (x₁+x₂) is ended and the polishing gap (x₁+x₂) is subsequently kept constant until the end of the process.

27. The method of claim 19, wherein at the beginning of the process the polishing begins with a parallel or substantially parallel polishing gap where (x₁+x₂) is 0 or substantially 0, and then the polishing gap (x₁+x₂) is increased to a specific size, and subsequently the polishing gap (x₁+x₂) is reduced in size in stages or continuously.

28. The method of claim 19, comprising a plurality of polishing steps, wherein a final polishing step has the smallest polishing gap (x₁+x₂) and makes up at least 10% of the total polishing time.

29. The method of claim 28, wherein the polishing gap (x₁+x₂) in the final polishing step is 50-110 μm.

30. The method of claim 28, wherein the polishing pressure in the final polishing step is 110-150 g/cm².

31. The method of claim 19, wherein the polishing pressure is changed in magnitude in stages or continuously.

32. The method of claim 19, comprising a plurality of polishing steps, employing a polishing gap (x₁+x₂) of 130-220 μm during at least one polishing step which makes up a maximum of 90% of the total polishing time.

33. The method of claim 32, wherein the polishing pressure in the at least one polishing step is 150-200 g/cm².

34. The method of claim 19, comprising at least two polishing steps, wherein the time duration of at least one polishing step is variable.

35. The method of claim 19, wherein during the double-side polishing of a semiconductor wafer, a thickness of the semiconductor wafer is measured.

36. The method of claim 19, wherein the result of measuring the thickness is used to define the time duration of a polishing step having a variable time duration.

37. The method of claim 19, further comprising a CMP single sided polishing of the front side of the semiconductor wafer.

38. The method of claim 37, further comprising epitaxially coating the CMP-polished front side of the semiconductor wafer.
